(19) United States
(12) Patent Application Publication
(10) Pub. No.: US 2018/0166275 A1
(43) Pub. Date: Jun. 14, 2018

(54) SEMICONDUCTOR TEMPLATES AND FABRICATION METHODS

(71) Applicant: Seren Photonics Limited, Pencoed, Bridgend Mid Glamorgan (GB)

(72) Inventor: Tao Wang, Sheffield South Yorkshire (GB)

(21) Appl. No.: 15/572,044

(22) PCT Filed: May 5, 2016
(86) PCT No.: PCT/GB2016/051288

§ 371 Date: Feb. 12, 2018

(30) Foreign Application Priority Data
May 5, 2015 (GB) 1507665.6

(51) Int. Cl. H01L 21/02

(52) U.S. Cl. CPC H01L 21/02458; H01L 21/02516; H01L 21/02603; H01L 21/0265; H01L 21/02609; H01L 21/0254

(57) ABSTRACT

A method of making a semi-polar semiconductor template comprises providing a semi-polar semiconductor wafer; etching the semiconductor wafer to form a regular semiconductor structure comprising a plurality of semiconductor regions (260) with a plurality of gaps between the regions, each of the regions (260) having a sidewall facing a respective one of the gaps, and growing semiconductor material over the semiconductor structure. The semiconductor material has a preferential growth direction (c) in which growth proceeds most rapidly from each of the sidewalls, and each of the sidewalls has at least a part which faces a vertical centre line of the respective one of the gaps so that growth in the preferential direction from said part extends towards said vertical centre line.

### FIELD OF THE INVENTION

The invention relates to semiconductor templates and methods of making semiconductor templates. In particular the invention relates to the production of semiconductor templates with high quality crystal structure. The templates can be used, for example, in the formation of light emitting diodes and solid state lasers.

### BACKGROUND TO THE INVENTION

Our earlier patent application PCT/GB2012/050458 describes a method of growing semiconductor crystal structures, for example GaN crystal structures, in which an irregular array of columns, also referred to as nano-columns, micro-columns, rods or pillars, is formed, and then a layer of semiconductor material is grown laterally from the sides of the columns and then over the tops of the columns, with a mask layer on the tops of the columns preventing growth from the tops of the columns, which helps to prevent the propagation of threading, edge, and mixed dislocations upwards from the tops of the columns. However it can be a problem with this method that a considerable fraction of basal stacking faults in the crystal structure of the semiconductor columns, still grow outwards and upwards from the sides of the columns and into the main semiconductor layer.

### SUMMARY OF THE INVENTION

The invention provides a method of making a semi-polar semiconductor template comprising: providing a semi-polar semiconductor wafer having a semiconductor layer with a top surface; etching the semiconductor layer to form an array of columns extending perpendicular to the top surface; and growing semiconductor material over the columns. The semiconductor material may have a preferential growth direction in which it tends to grow most quickly, at least under some growth conditions. The columns may be arranged, for example when viewed in the direction perpendicular to the top surface, to be in a regular array comprising a series of rows of columns. The rows may be arranged, for example being offset from each other in the direction perpendicular to the preferential growth direction, so that growth in the preferential direction from one of the columns in one of the rows extends between adjacent columns in the adjacent row.

This arrangement tends to encourage growth in the preferential growth direction which can help to block the propagation of basal stacking faults (BSFs) which propagate in other directions. It can also provide an even surface on the finished template.

For group III nitride materials, in which BSFs tend to propagate in the a- and m-directions only, a preferential growth direction is the c-direction, in which BSFs do not propagate.

The wafer may be a (11-22) plane wafer, i.e. having its top surface in the (11-22) plane. Alternatively it may be of another semi-polar orientation such as (1-101), (10 11), (10-13), (20-21) or (20-2-1).

The rows may each extend in the horizontal direction perpendicular to the preferential growth direction. For example in a square or rhombic array of columns the rows may extend along the diagonals of the squares or rhombuses of the array, or in a hexagonal array the rows may extend between nearest neighbours of the array.

The columns are typically of the order of a few hundred nanometers s to 10s of micrometers in height and of a few hundred nanometers to 10s of micrometers in diameter may therefore be referred to as nano-columns or nano-rods or micro-columns or micro-rods.

The regular array may be a square array, or other rectangular or rhombic array or other oblique array. When seen in the direction perpendicular to the top surface, the preferential growth direction may extend along a diagonal of the square or rhombic array. In other words the component of the preferential growth direction in the horizontal plane may extend along the diagonal of the square or rhombic array. Alternatively the regular array may be a hexagonal array, or a centred rectangular array.

Each of the columns may have a cap on its top during growth of the semiconductor material. The cap may comprise at least one mask layer or part of a mask layer. The cap may be arranged to prevent growth of the semiconductor material from the top of the column. The height of the cap may be at least high enough so that the propagation of BSFs from the highest point on the side of one of the columns, in a straight line in a BSF propagation direction of the material, is blocked by the cap on another of the columns. The height of the cap may also be high enough so that growth in a straight line in the preferential growth direction from the highest point on the side of one of the columns is blocked by the cap on another of the columns.

The semiconductor layer may be supported on a substrate. The substrate may comprise at least one of sapphire, silicon and silicon carbide.

The semiconductor layer may be formed of a group III nitride. For example it may be GaN. Methods of growing various semipolar orientations of GaN and other group III nitrides on patterned substrates of sapphire and silicon are well known.

The cap may be formed of at least one of silicon dioxide and silicon nitride. Other materials that prevent growth from the top of the column may also be used.

The invention further provides a semiconductor template comprising an array of columns formed of semiconductor material, each including a cap, which may be formed of at least a mask material, formed on its top, and a semiconductor material extending between the columns and over the top of the columns to form a continuous layer and having a preferential growth direction, wherein the columns are arranged, to be in a regular array comprising a series of rows of columns, the rows being offset from each other in the direction perpendicular to the preferential growth direction, so that growth in a straight line in the preferential growth direction from one of the columns in one of the rows extends between adjacent columns in the adjacent row. The offset may be equal to half of the period or interval of the columns along the row, i.e. half the distance between the centres of adjacent columns.

The invention further provides a semiconductor template comprising an array of columns formed of semiconductor material, each including a cap formed of a mask material formed on its top, and a semiconductor material extending between the columns and over the top of the columns to form a continuous layer, wherein the semiconductor material has a preferential growth direction in which it tends to grow most rapidly, at least under some growth conditions, wherein the columns are arranged in a regular array comprising a series of rows of columns, the rows being offset from each other in the direction perpendicular to the preferential growth direction.

The invention further provides a method of making a semiconductor template comprising: providing a semiconductor wafer; etching the semiconductor wafer to form an array of columns each comprising a main part and a cap on its top; and growing semiconductor material from the main parts of the columns over the columns; wherein the material has a BSF propagation direction in which BSFs will propagate during growth of the material, and the height of the caps is such that growth from the top of the main part of one of the columns in a straight line in the BSF propagation direction will be blocked by the cap of another of the columns.

The array may be regular or irregular. For example, if the array is irregular it may be formed using annealed nickel as a mask when etching the columns. If the array is regular then the etching mask may be formed using photolithography.

Each column may have more than one nearest neighbour all equidistant from it.

The semiconductor material may have a preferential growth direction in which, under at least some growth conditions, it grows most rapidly from the columns, and the height of the cap may be high enough so that growth in a straight line in the preferential direction from the highest point on the side of the main part of one of the columns is blocked by the top of the cap on the nearest column in the preferential growth direction.

Since growth in the preferential direction tends to block growth in other directions, this means that propagation of dislocations or basal stacking faults in any direction tends to be blocked.

The invention further provides a method of making a semi-polar semiconductor template comprising: providing a semi-polar semiconductor wafer; etching the semiconductor wafer to form a regular semiconductor structure comprising a plurality of semiconductor regions with a plurality of gaps between the regions, each of the regions having a sidewall facing a respective one of the gaps, and growing semiconductor material over the semiconductor structure; wherein the semiconductor material has a preferential growth direction in which growth proceeds most rapidly from each of the sidewalls, and each of the sidewalls has at least a part which faces a vertical centre line of the respective one of the gaps so that growth in the preferential direction from said part extends towards said vertical centre line.

The invention further provides a semiconductor template comprising a regular semiconductor structure comprising a plurality of semiconductor regions with a plurality of gaps between the regions, each of the regions having a sidewall facing a respective one of the gaps, and a semiconductor material formed within the gaps and over the top of the columns to form a continuous layer and having a preferential growth direction, wherein each of the sidewalls has at least a part which faces a vertical centre line of the respective one of the gaps.

The invention further provides a method of making a semi-polar semiconductor template comprising: providing a semi-polar semiconductor wafer; etching the semiconductor wafer to form a regular semiconductor structure comprising a plurality of semiconductor regions with a plurality of gaps between the regions, each of the regions having a sidewall facing a respective one of the gaps, wherein the gaps are arranged in parallel rows, growing semiconductor material over the semiconductor structure; wherein the semiconductor material has a preferential growth direction in which growth proceeds most rapidly from each of the sidewalls, each of the rows extends in the direction perpendicular to the preferential growth direction, and the rows are offset from each other in the direction perpendicular to the preferential growth direction.

The invention further provides a semiconductor template comprising a regular semiconductor structure comprising a plurality of semiconductor regions with a plurality of gaps between the regions, each of the regions having a sidewall facing a respective one of the gaps, and a semiconductor material formed within the gaps and over the top of the columns to form a continuous layer and having a preferential growth direction, wherein the semiconductor material has a preferential growth direction in which growth proceeds most rapidly from each of the sidewalls, the gaps are arranged in rows, each of the rows extends in the direction perpendicular to the preferential growth direction, and the rows are offset from each other in the direction perpendicular to the preferential growth direction.

The rows may be offset from each other in the direction perpendicular to the preferential growth direction by a distance equal to half of the period or interval of the gaps.

The regions comprise columns, in which case the gaps will be interconnected. Alternatively the gaps may comprise holes, in which case the regions will be interconnected.

The sidewall of each of the holes may be flat, or may include a flat region.

The method or wafer may further comprise, in any workable combination, any one or more of the steps or features of the preferred embodiments of the invention, which will now be described, by way of example only, with reference to the accompanying drawings.

### BRIEF DESCRIPTION OF THE DRAWINGS

FIGS. 1a to 1e show the steps in the formation of a template according an embodiment of the invention;

FIG. 2 is a top view of a column array as shown in FIG. 1C;

FIG. 3 is a diagram showing part of the column array of FIG. 2 with the associated crystal growth directions indicated;

FIG. 4 is a side view of part of the column array in the direction of arrow IV in FIG. 3;

FIG. 5 is a side view of part of the column array in the direction of arrow V in FIG. 3;

FIG. 6 is a top view of a column array used in a method according to a further embodiment of the invention;

FIG. 7 is a plan view of a column array of a template according to a further embodiment of the invention;

FIG. 8 is a plan view of a column array of a template according to a further embodiment of the invention;

FIG. 9 is a plan view of a column array of a template according to a further embodiment of the invention;

FIG. 10 is a SEM image of the top of a GaN crystal structure during formation of a template according to an embodiment of the invention;

FIG. 11 is a SEM side view of the structure of FIG. 10;

FIG. 12a is a diagram showing the blocking of dislocations in a (11-22) GaN crystal grown on a micro-column array;

FIG. 12b includes two contour plots of the percentage of dislocations remaining as a function of micro-rod diameter and micro-rod spacing, with micro-rod diameters of 1.4 μm and 0.4 μm respectively;

FIG. 13 is a top view of a semiconductor structure forming part of a template according to a further embodiment of the invention;

FIG. 14 is a top view of a semiconductor structure forming part of a template according to a further embodiment of the invention;

FIG. 15 is a top view of a semiconductor structure forming part of a template according to a further embodiment of the invention;

FIG. 16 is a top view of a semiconductor structure forming part of a template according to a further embodiment of the invention;

FIGS. 17a and 17b are diagrams of the group III nitride crystal structure showing polar, nonpolar, and semipolar surfaces;

FIGS. 18a and 18b are diagrams of the group III nitride crystal structure showing the (11-22), (10-11) and (20-21) semipolar planes; and

FIGS. 19a and 19b are diagrams showing the orientation of the crystal structure under a top surface in various polar, nonpolar, and semipolar planes.

### DESCRIPTION OF THE PREFERRED EMBODIMENTS

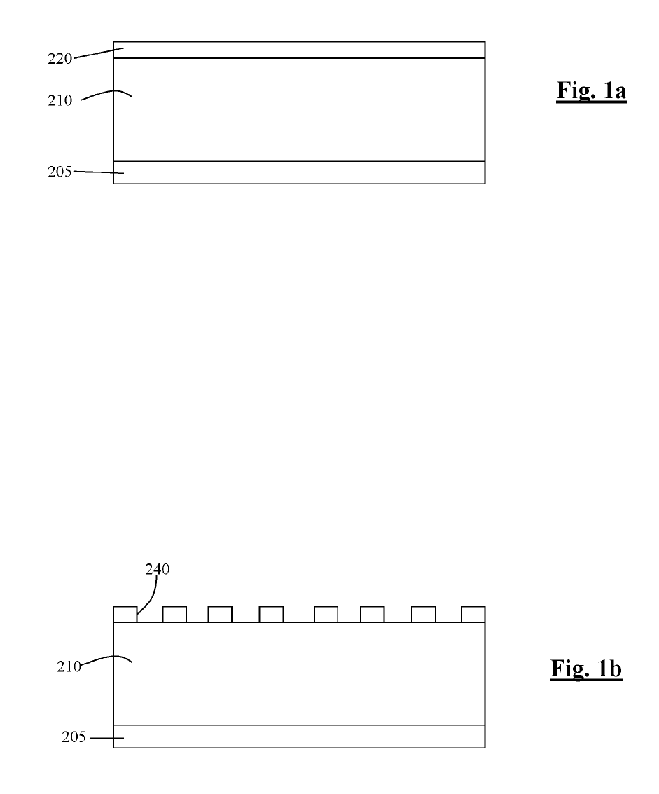

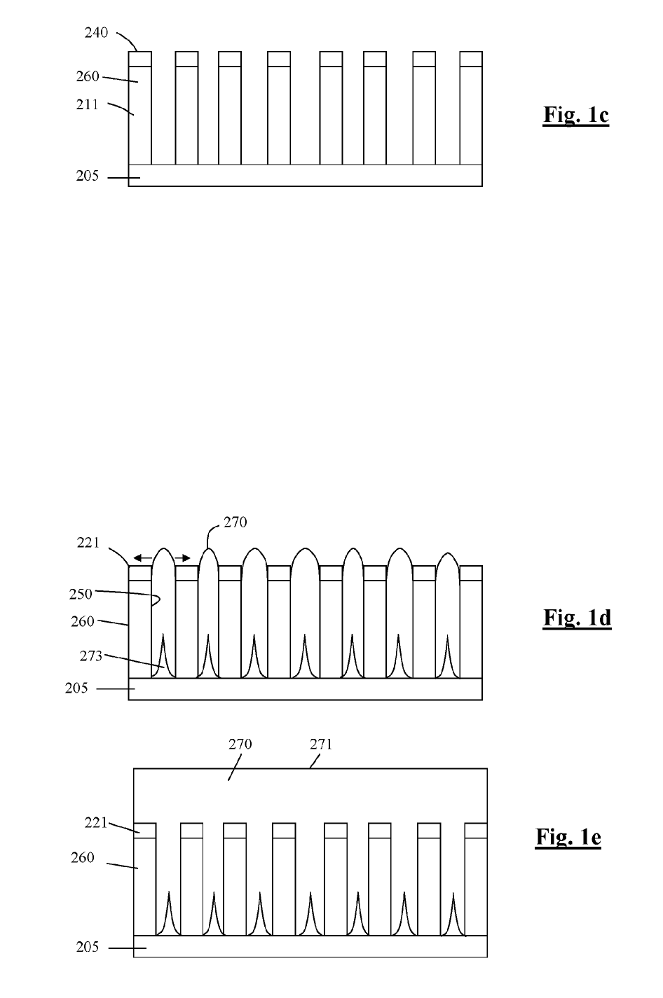

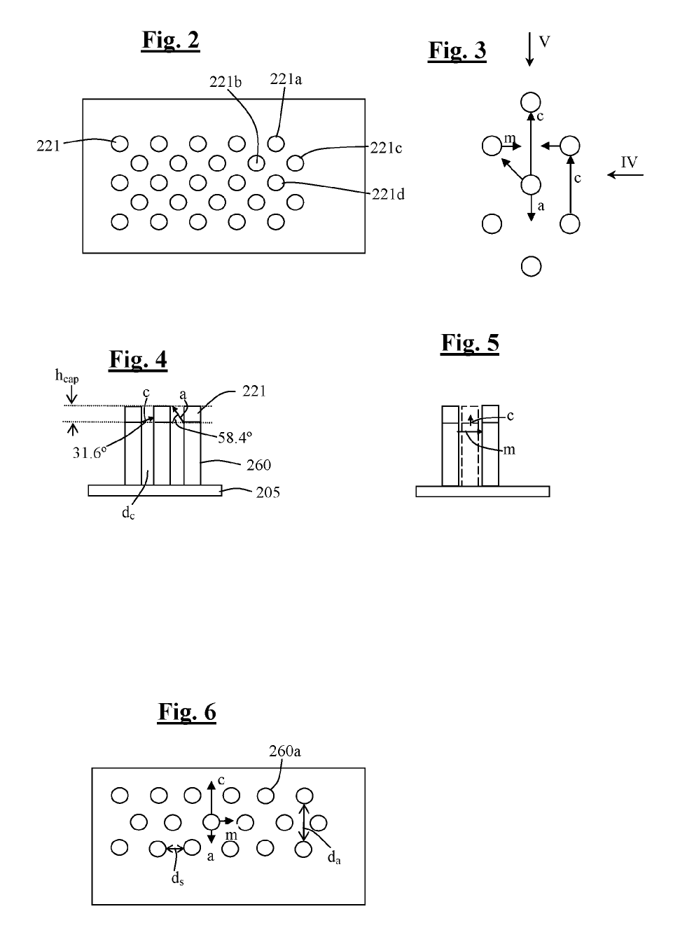

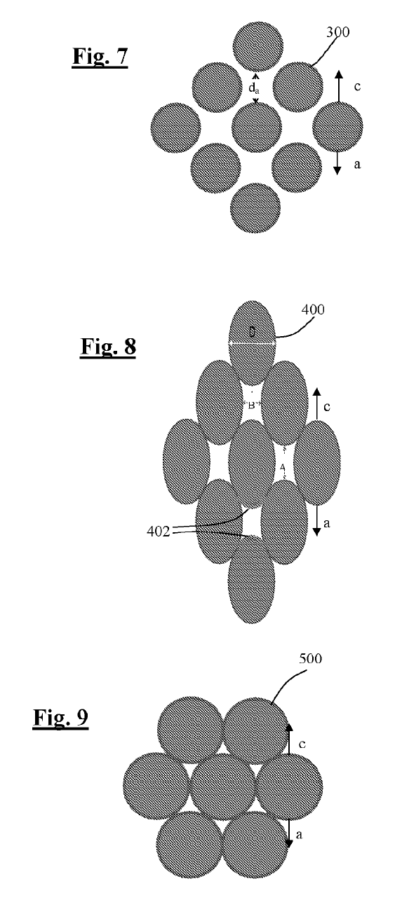

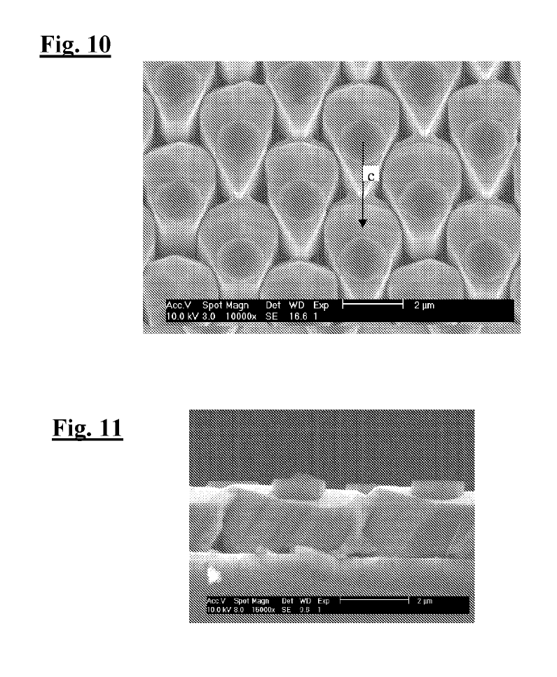

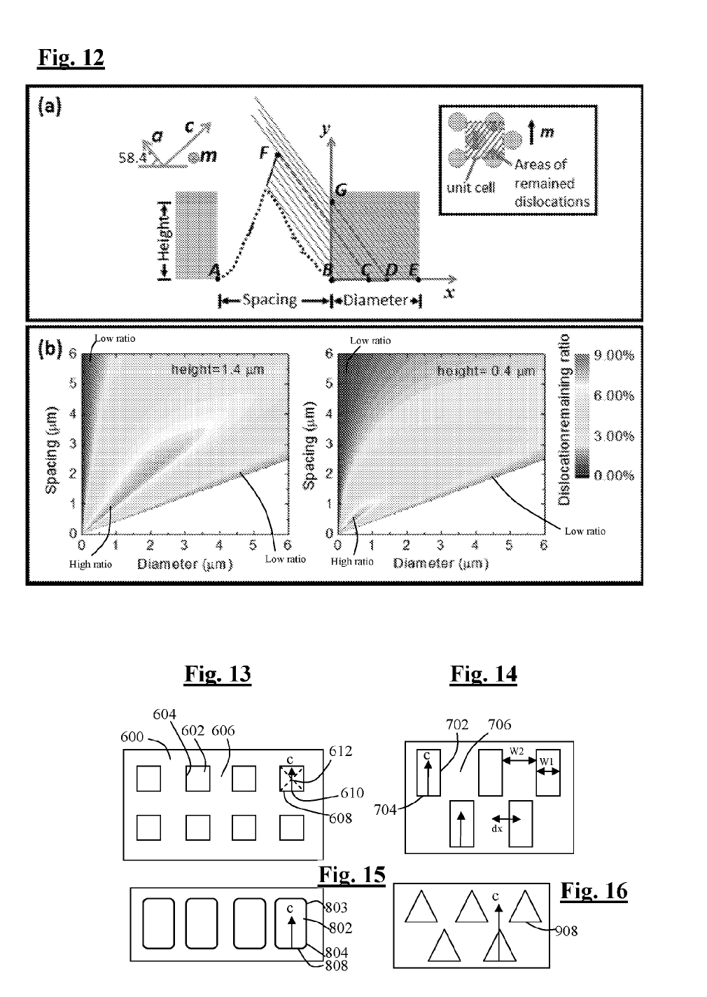

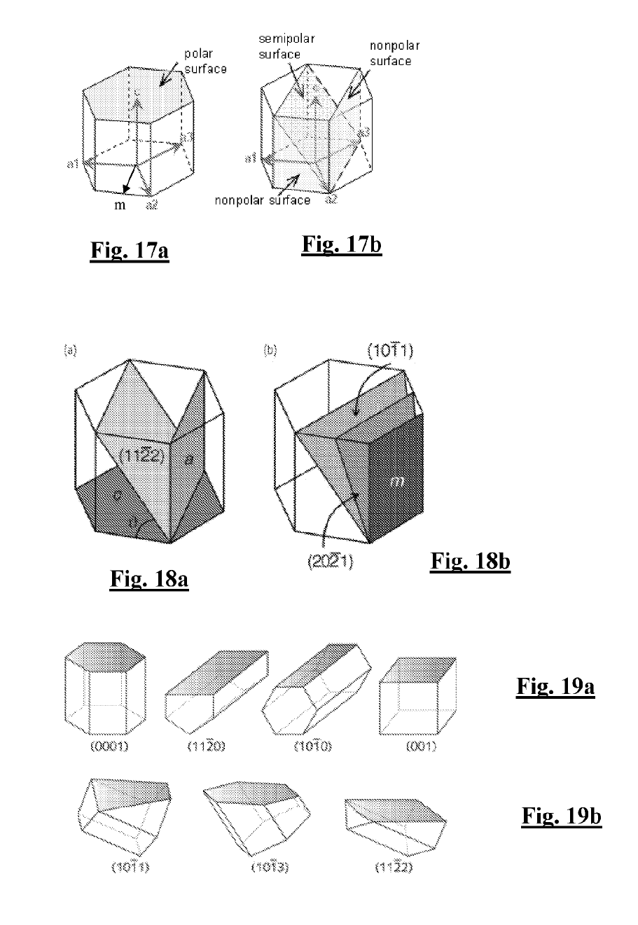

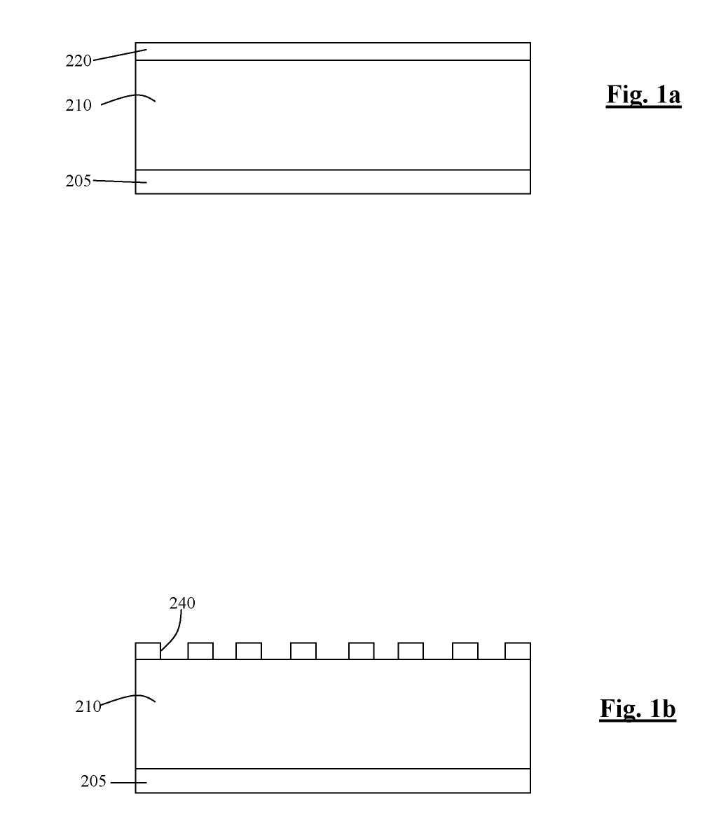

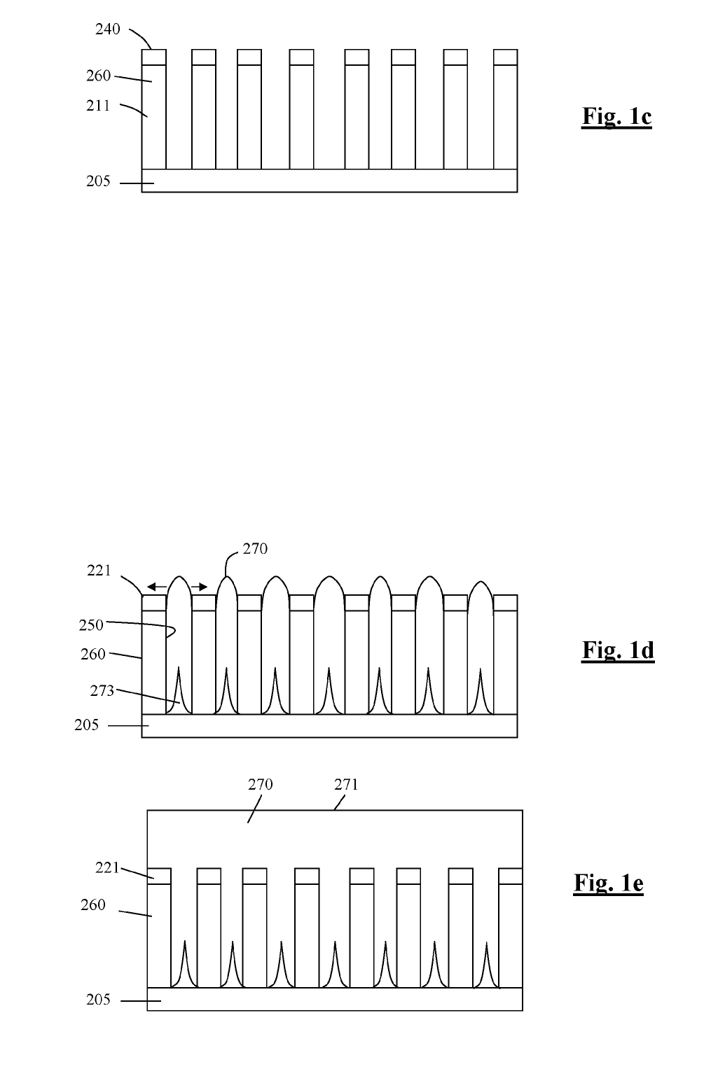

Referring to FIG. 1a, the first step of fabricating a semiconductor template is providing a suitable semiconductor wafer 201. The wafer 201 is conventional and is made up of a substrate 205, which in this case comprises a layer of sapphire, over which is a semiconductor layer 210 formed of gallium nitride (GaN). Other materials can be used. For example the substrate may be silicon (either planar or patterned) or silicon carbide (either planar or patterned). The semiconductor may be another suitable material, for example another group III nitride such as indium gallium nitride (InGaN) or aluminium gallium nitride (AlGaN) or indium nitride (InN) or aluminium nitride (AlN). The semiconductor wafer is semipolar. Specifically in this embodiment the GaN is orientated so that its top surface, parallel to the plane of the substrate, which is referred to herein as the horizontal plane, is in the (11-22) plane. A buffer layer or nucleation layer, for example of high temperature MN with a thickness from 10 nm to a few micrometer or a thin low temperature GaN or a thin low temperature AlN, may be provided between the substrate 205 and the GaN layer 210, to partially compensate the lattice-mismatch between the GaN and substrate crystal structures.

A mask layer 220 is provided over the semiconductor layer 210, for example using plasma-enhanced chemical vapour deposition (PECVD) or thermal evaporation or sputter evaporation. The mask layer 220 is formed of silicon dioxide, although there are suitable alternative materials for this layer e.g. silicon nitride.

With reference to FIG. 1b, the mask layer 220 is etched using standard photolithographic techniques to leave a mask comprising an array of mask elements in the form of short columns which may be nano-columns or micro-columns (also referred to as nano-rods or nano-pillars or micro-rods or micro-pillars) 240 of silicon dioxide distributed in a regular pattern over the GaN layer 210. The columns 240 resulting from the previous step serve to mask some areas of the GaN layer 210, and to define which areas (i.e. those exposed areas in the spaces between the columns 240) of the GaN layer 210 will be etched.

Referring to FIG. 1c, at the next step the GaN layer 210 is etched, for example by inductively coupled plasma etching, with the short columns 240 that were formed in the previous steps used as mask elements making up a mask. This step involves etching though the GaN layer 210, as shown in FIG. 1c. In this embodiment the etching is continued until it has reached the substrate 205, though in other embodiments it may proceed only partly through the GaN layer 210, or down to the buffer layer if one is present. This step results in a column structure, as shown in FIG. 1c, in which columns 260 extend upwards in the vertical direction from the sapphire substrate 205, each column 260 comprising a respective part 211 of the GaN layer 210, and a cap formed from the respective part 240 of the mask layer 220. Therefore the etching of this step produces exposed surfaces 250 of the GaN, which comprise the sides of the columns 260. The diameter and cross sectional shape of each column 260 is approximately constant from top to bottom, being approximately the same as the diameter and shape of the surface area covered by its respective part 240 of the mask, although in practice some tapering of the columns generally occurs.

Referring to FIG. 1d, the GaN column array is used as a template for deposition of GaN 270 onto the sides 250 of the GaN columns 211 by metalorganic chemical vapour deposition (MOCVD) or MBE or HVPE for overgrowth. The re-growth starts on the sidewall 250 of GaN columns (firstly laterally and then vertically), where the GaN is exposed. The growth proceeds at different rates in different directions, as will be described in more detail below. This forms layers on the sides of the columns. These grow outwards from the columns and towards each other until they meet where the layers are thickest. This then prevents further growth in the volume below the meeting point. This leaves, in some cases, the volume 273 as hollow gaps or cavities around the base of each of the columns 260. These gaps may be interconnected to form a cavity, which is labyrinthine in form and extends between all, or substantially all of the columns. The SiO₂ caps or mask elements 221 on the top of the columns will prevent GaN growth on their top. Referring to FIG. 1e, when the growing face of the GaN reaches above the height of the SiO₂ mask elements 221 the GaN re-growth progresses laterally over the top of the SiO₂ mask, and eventually coalesces to form a continuous layer extending over the top of the mask, and having a smooth surface 271 as shown in FIG. 1e.

Once the growth has been completed, the substrate 205 can be removed, which may be desirable in some applications. Removal of the substrate will generally include removal of the bottom end of the columns 260. This can be made easier by the presence of the hollow volume 273 around the base of the columns. The bases of the columns 260 may be removed up to a level which is below the top of the hollow volume 273. This can result in a very uniform structure with low levels of strain.

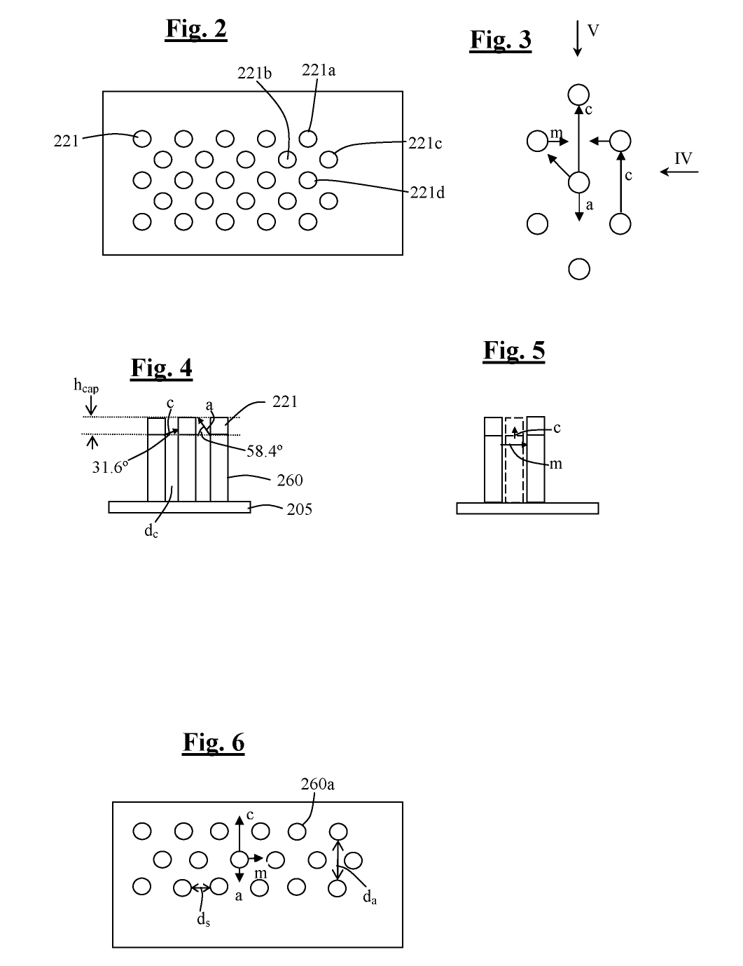

Referring to FIG. 2, the mask is formed as a regular array of islands or columns 221. In this embodiment the array is a square array. The etched columns 260 are therefore of course spaced apart in the same square array. The orientation of the array relative to the crystal structure of the GaN layer is selected so that the growth of the GaN layer proceeds in an advantageous manner that blocks the growth of BSFs and threading and other dislocations. For clarity of description, the (11-22) plane, which is parallel with the top surface of the wafer and the finished template, will be referred to as the horizontal plane, and the direction perpendicular to that, i.e. the direction in which the columns 260 extend from the substrate, will be referred to as the vertical direction.

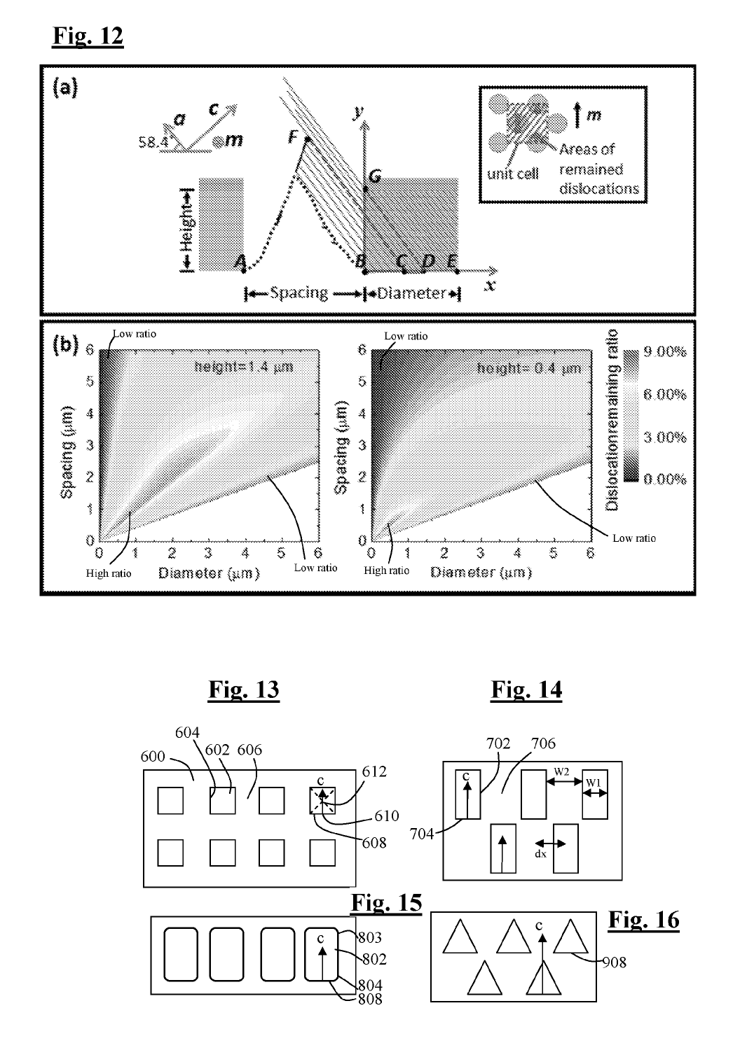

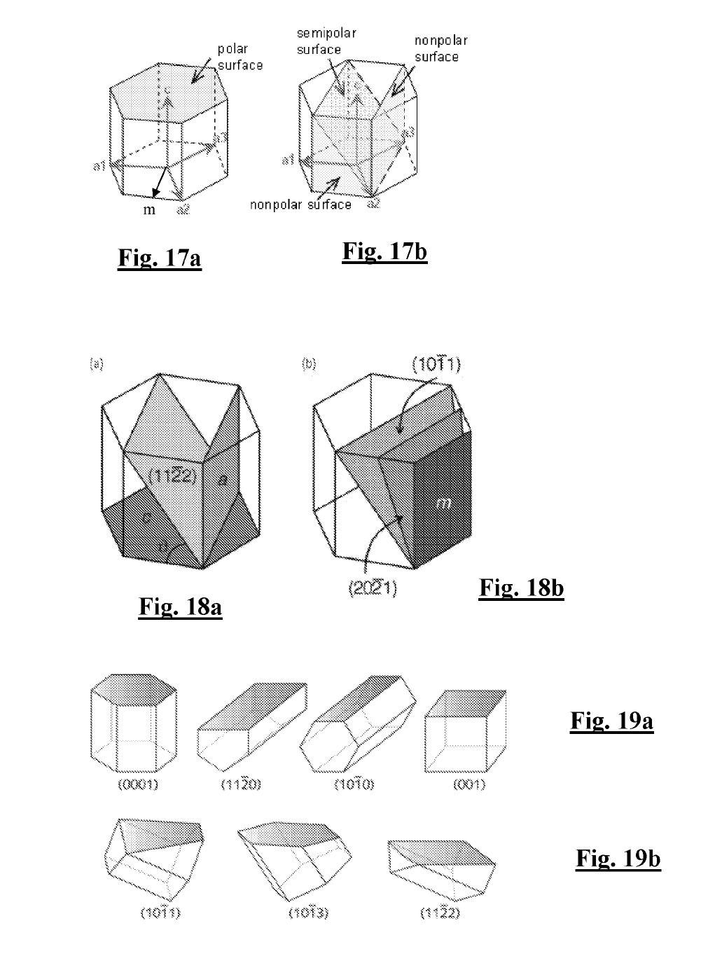

As is well known, crystal growth speed varies with direction, as well as being dependent on growth conditions and in particular the III/V ratio of the growth material, and the different growth speeds in different directions are used in this and other embodiments to maximize the blocking of both dislocations and basal stacking faults. The various directions, which are defined by the crystal lattice structure, and each associated with a specific plane in the crystal lattice structure, will therefore now be described for this embodiment. A more general description follows with reference to FIGS. 12a to 14b. The square array is arranged such that the smallest squares in the array, for example as made up by the four columns 221a, 221b, 221c, 221d, each have a diagonal which is aligned with the c-direction of the crystal structure when that c-direction is projected onto the (11-22) plane, i.e. the horizontal component of the c-direction. This can be seen in FIG. 3, which shows the c-direction, a-direction, and m-direction all projected onto the (11-22) plane, i.e. their horizontal components. As shown in FIG. 4, the c-direction is in fact inclined upwards at an angle of 31.6° from the horizontal, and the a-direction has a horizontal component which is in the opposite direction to that of the c-direction, and is inclined upwards at an angle of 58.4° to the horizontal. Similarly, as can be seen in FIG. 5, the m-direction of the crystal structure lies in the horizontal plane and is perpendicular to the c-direction.

It should also be noted that the height of the SiO₂ caps on the columns is preferably carefully controlled so that basal stacking faults (BSFs), propagated from the crystal structure of the semiconductor columns, can be blocked. BSFs can be extended to the overgrown layers from the crystal structure of the semiconductor columns, but along the m- or a-direction only. The BSFs can be eliminated if growth is along c-direction. The BSFs generated along the m-direction can be naturally blocked by the neighbouring columns as the m-direction is along the horizontal direction. The BSFs generated due to the growth along the a-direction can be effectively blocked by the SiO2 cap 221 whose thickness is selected to achieve that.

As can be seen in FIG. 4, it is preferable that growth in the a-direction from the highest point on the main part of each of the columns is blocked by the SiO₂ cap 221 on the adjacent column in that direction of growth. In simple geometric terms this means that a straight line at the BSF propagation direction (in this case the a-direction) from the top of the main part of the column not including the cap, on the side of the column facing in the (horizontal component of the) a-direction, hits the cap of the nearest column in that direction. Therefore the height of the SiO₂ cap h_{cap} also preferably needs to be selected such that

h_{cap}>dₐtan 58.4

where dₐ is the smallest gap between adjacent columns in the horizontal component of the a-direction.

During growth of the GaN 270 as shown in FIGS. 1d and 1e, a number of factors come into effect which tend to block the growth of BSFs and dislocations in the crystal. Firstly, as shown in FIGS. 4 and 5, the relatively fast growth in the c-direction, which is the preferential growth direction of GaN, because it is, at least under some growth conditions, faster than growth in the a-direction and m-direction, tends to block off growth in those two directions. Also, growth in the a-direction from the top of the GaN column 260 preferably hits the top of the adjacent, i.e. nearest, column in that direction of growth. This will be after it has passed between two columns that are nearer to the column from which the growth is occurring, but offset from the c-direction. Therefore, the growth in the c-direction tends to form the bulk of the GaN layer 270 that grows over the columns because it predominates over growth in all other directions.

Any of the regular column arrays described above can be used in this way, with the spacing reduced to achieve this blocking. Alternatively a random column array can be used, for example using annealed nickel as the mask for etching the columns.

Referring to FIG. 6, in a method according to a second embodiment of the invention, the basic process is the same as in the first embodiment. However, the array of columns 260a is a hexagonal array in which each column 260 is surrounded by six others which are all nearest neighbours to it, and equidistant from it, and located at the corners of a hexagon. The array is orientated so that the c-direction from the centre of each column, and therefore the c-direction growth from each column, passes between two of the nearest columns and equidistant between them. This means that the a-direction from each column 260a also passes between two of the nearest columns and equidistant between them. The m-direction from each column is directly towards one of the nearest adjacent columns. For the most effective blocking of threading dislocations in this embodiment, the height of the SiO₂ cap h_{cap} again needs to be selected such that

h_{cap}>dₐtan 58.4°

where dₐ is the gap between adjacent columns in the a-direction, as indicated in FIG. 6. It will be noted that, in this embodiment, growth towards the nearest adjacent column is in the m direction which is in the horizontal plane. Therefore this growth will be blocked by the nearest adjacent column.

It will be appreciated that other embodiments of the invention will vary from those described above. For example, in each of the embodiments described above, the columns can be considered as arranged in rows, the rows extending in the horizontal direction of the horizontal component of the m-direction of the crystal structure. These rows extend along the diagonals of the square array in FIG. 2, and along the direction through opposite corners of the hexagonal array of FIG. 6. In each case, these rows could be spaced apart from each other by slightly more, or less, than is needed for a strict square or hexagonal array, for example giving a rhombic array, and the method would work equally well, especially if the column cap thickness was within the required range. In fact it will be noted that the hexagonal array of FIG. 6 can be considered as a rhombic array made up of groups of four columns in a rhombus, with a long diagonal dₐ and a short diagonal dₛ. Increasing the spacing of the rows of columns from that of FIG. 2 will, at some point, result in the array of FIG. 6, and other row spacings between these two, or closer or further apart, will also work in a similar way. Similarly the offset between adjacent rows of columns can be varied slightly from the 2D Bravais lattice arrangements referred to in which it is equal to half the period of the columns along the rows.

Referring to FIG. 7, in templates similar to that of FIG. 2, with a square array of columns 300 with the horizontal components of the c- and a-directions aligned with the diagonals of the squares of the array, the distance dₐ between each column and its nearest neighbour in the a-direction can be varied, and if it is reduced further, even to the point where the columns touch or almost touch their nearest neighbours, the crystal growth will tend to be more limited to the c-direction growth, and vertical growth on c-direction growth, and this can further improve the quality of the finished template.

Referring to FIG. 8, in a modification to this arrangement, the columns 400 are not of circular, but of oval or ellipsoidal cross section, being wider in the c-direction than in the perpendicular direction. This gives a greater spacing A between columns in the a-direction, than the spacing B in the perpendicular m-direction. In this embodiment the columns 400 are in a rhombic array with the longer diagonals, as the wider column dimension, in the c-direction, but they are close enough to be touching each other. Growth from the sides of the columns is therefore concentrated in small areas 402 on the exposed sides of the columns facing in the c- and a-directions. In practice making the columns so that they are actually touching would be very difficult but getting them as close together as possible may be advantageous, in a similar way to that with a square array as will be described in more detail below with reference to FIGS. 12a and 12b.

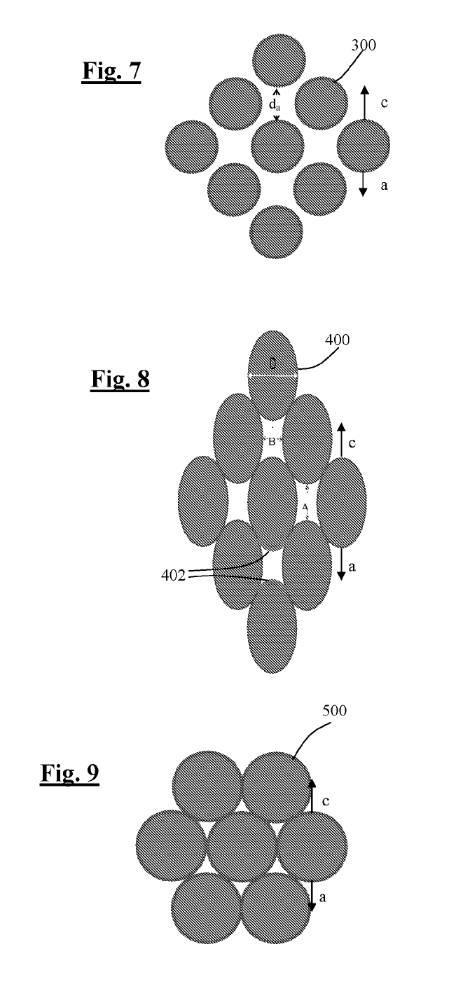

Referring to FIG. 9, in a further modification, the columns 500 are circular and arranged in a close packed hexagonal array so that each is in contact, or as nearly in contact as is practically possible, with six nearest neighbours. Again, the array is aligned so that the c- and a-directions from each column extend between, or towards the line of contact between, two of the nearest neighbours.

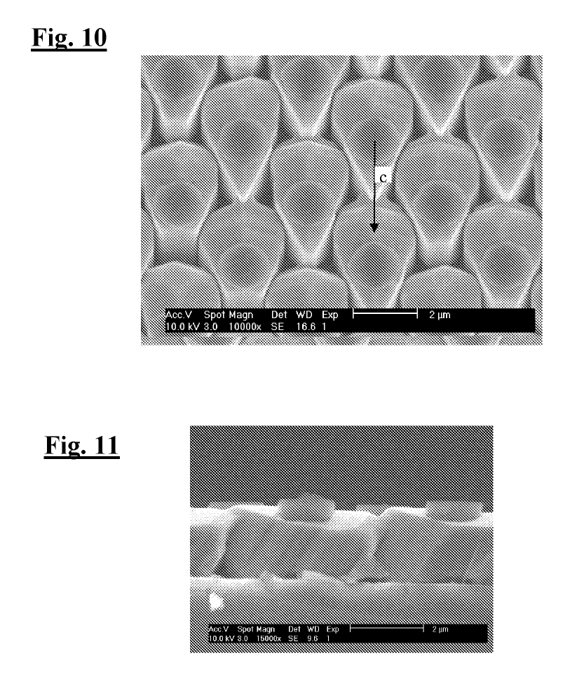

Referring to FIG. 10, the growth from the columns during formation of a template, similar to that of FIG. 2 is shown. The c-direction is marked on FIG. 10, and is from right to left in FIG. 11. Growth in the c- and a-directions dominates, but then growth continues sideways and upwards from that growth. It can be seen that the growth on the c-direction side of the column extends upwards more rapidly than the growth on the a-direction side. This means that, as the growth progresses beyond the point shown in these figures, the growth based on c-direction growth will tend to extend over the top of the growth based on a-direction growth, and will therefore dominate in the final continuous layer that extends over the tops of the columns.

Referring to FIGS. 12a and 12b, the percentage of threading dislocations that will propagate in the crystal can be modelled to determine preferred dimensions of the column array. FIG. 12a shows a section through a square array of columns in which segment AE represents one period of the column structure. Based on transmission electron microscopy observations, only the dislocations located in the line segment CD, propagating in the ‘a’ direction, have a chance to propagate to the surface of the crystal, while other dislocations are blocked either during the first coalescence when c-direction growth from adjacent columns blocks propagation of the dislocations in the a direction (those emanating from line segment BC) or by the SiO₂ mask (those emanating from line segment DE). Points C and D are the projections of the top point F of the first coalescence front and the top point G of the sidewall of the micro-column onto the sapphire surface along the a-direction, respectively. By integrating the line segment CD along the m-direction (i.e. into the plane of FIG. 12a) an area where the dislocations have a chance to propagate to the surface is obtained, as shown in the inset in FIG. 12a. The ratio of this area to the area of integrated line segment AE along the m-direction can be treated as a dislocation remaining ratio. For simplicity, any decrease in dislocation density due to the lateral overgrowth along the a-direction and a very small number of extra dislocations generated during the coalescence process are not taken into account.

FIG. 12b shows the simulation results describing the relationship between the dislocation remaining ratio and the column diameter and spacing, where the height of the columns is set at 0.4 μm and 1.4 μm respectively. In each case the simulation is limited to column diameters below 6 μm. It will be appreciated that, since the spacing is measured on the diagonal of the square array, the minimum spacing is ((√2)-1)D, where D is the column diameter. This is the point where the columns are just in contact with their closest neighbours. It can be seen that there are two areas of low dislocations. One is close to the vertical axis i.e. at very low column diameters. Therefore in order to make use of this the columns may be arranged so that their diameter is no more than 20% of their spacing in the direction of the diagonal of the square (or rectangular) array, or even no more than 10% of their spacing. The other is at, or close to, the minimum column spacing where the columns are in contact. Therefore in order to make use of this, the columns may be arranged so that they are in contact with their closest neighbours, or spaced from their nearest neighbours by no more than 10% of their diameter, or even no more than 5% of their diameter. It can also be seen that the areas of low dislocations are greater for columns of height 0.4 μm than of height 1.4 μm. It may therefore be preferable for the columns to have a height of no more than or even no more than 0.5 μm. For columns of non-circular cross section, the diameter D can be defined as D=2√(A/π) where A is the cross sectional area of the column, and the same preferred relationships between diameter and spacing will still apply in approximately the same way. Also with other column arrays such as those described above with reference to FIGS. 8 and 9, the advantages of having the columns as close together as is practical may still apply.

While the mask layer and columns in the embodiments described are of approximately circular cross section, other cross sections can be used, depending on the accuracy of the photolithographic process. For example in a modification to the embodiment of FIG. 2, the columns are of square cross section, with the sides of the square columns in vertical planes parallel to the c-direction and the m-direction. This has the advantage of encouraging growth in the preferential direction. Alternatively octagonal cross section columns can be used. Other cross sections such as rectangular and trapezoidal may also be used.

Referring to FIG. 13, rather than the etched semiconductor layer forming an array of columns with gaps between the columns, it may form a regular structure 600 of semiconductor material with an array of holes 602 therein. The holes 602 may be of substantially constant cross section and extend downwards from the top of the semiconductor layer. In order to etch the holes, the mask layer may be in the form of a continuous layer with holes through it. The mask layer may be formed by lithographic techniques. In other respects the method for forming the semiconductor structure 600 may correspond to that for forming the array of columns as described above, and will not be described again here in detail. The holes 602 may each have one or more side walls 604, which may be straight or curved in the horizontal direction. The side walls 604 will be generally vertical, and generally straight in the vertical direction, within the limits of the etching process used to form the holes. The regions 606 of the semiconductor layer between the holes 602 are of course connected to each other to form a single continuous layer extending around the holes 602. The side walls 604 form the boundaries between the holes and the semiconductor material in the regions 606 between the holes 602, and can therefore be considered side walls of the regions 608 of semiconductor material as well as side walls of the holes.

The holes 602 may be of square cross section as shown in FIG. 13, or they may have four bowed or curved sides, in a similar arrangement to that of FIG. 8. Alternatively the sides may be bowed outwards, rather than inwards as in FIG. 8. They may be of other rectangular cross sections, or of triangular or other polyhedral cross sections. Referring again to FIG. 13, at least one side wall 608 of each of the holes 602 may be flat or substantially flat, and may be perpendicular to the horizontal component of the c-direction. A part of that flat side wall 608, for example the central part 610 of it as seen in FIG. 13, will face the vertical centre line 612 of the hole 602, i.e. the vertical line furthest from any side wall of the hole. In the case of a square cross section hole the centre line 612 will be at the centre of the square cross section i.e. at the intersection of its diagonals as indicated in FIG. 13. The holes 602 may be arranged in regular rows. For example the rows may extend in the horizontal direction perpendicular to the preferential growth direction, and the holes in each row may be aligned with those in the adjacent row as shown in FIG. 13, or they may be offset in the horizontal direction perpendicular to the preferential growth direction as shown in FIG. 14.

Referring to FIG. 14, each of the holes 702 may be wider in the direction of the horizontal component of the c-direction than in the perpendicular direction (which may be the direction of the horizontal component of the m-direction). For example they may be of generally rectangular cross section with the shorter sides 704 of the rectangle facing in the direction of the horizontal component of the c-direction. The offset dx may be equal to half the period or interval of the holes, i.e. half the distance between the centres of adjacent holes in the row, or half the sum of the width w1 of the hole and the width w2 of the semiconductor region 706 between the holes in the horizontal direction perpendicular to the preferential growth direction. This means that growth from the sidewall 704 from which the c-direction growth comes, will extend across the hole 702 and then over the semiconductor region 706 between the two nearest holes in the next row. This offsetting of the rows of holes may be used with other suitable hole shapes.

Referring to FIG. 15, the holes 802 may be rectangular, similar to those of FIG. 14, but with more rounded corners 803. The degree of rounding of the corners 803 may be different. For example the corners 804 at the edges of the sidewall 808 from which the c-direction growth will extend may be less rounded than those at the opposite end of the holes 802.

Referring to FIG. 16, the holes may be arranged so that they have one flat side wall 908 facing in the direction of the horizontal component of the preferential growth direction, but no flat side wall facing in the opposite direction. For example the holes may be of triangular cross section as shown, or they may be of pentagonal cross section, or all other side walls apart from the one flat side wall may be curved.

Referring to FIGS. 12a and 12b, in general terms, the polar plane in group III nitride crystal structures is perpendicular to the c-direction, non-polar planes are parallel to the c-direction, and semi-polar planes are all planes which are inclined to (i.e. neither parallel nor perpendicular to) the c-direction. Referring to FIGS. 13a and 13b, while the embodiments described above use wafers with a (11-22) orientation, in other embodiments the wafer orientation is (1-101), (10-11), (10-13), (20-21) or (20-2-1). FIG. 14a shows the orientation of the crystal structure under a crystal top surface having various polar and nonpolar orientations, and FIG. 14b shows the orientation of the crystal structure under a crystal top surface having various semipolar orientations as used in various embodiments of the invention.

1. A method of making a semi-polar semiconductor template comprising:
providing a semi-polar semiconductor wafer;
etching the semiconductor wafer to form a regular array of columns; and
growing semiconductor material over the columns; wherein
the semiconductor material has a preferential growth direction in which growth proceeds most rapidly from each of the columns, and the array comprises a series of rows of columns, the rows being offset from each other in the direction perpendicular to the preferential growth direction, so that growth in the preferential direction from one of the columns in one of the rows extends between adjacent columns in the adjacent row.

2. A method according to claim 1 wherein the wafer has a top surface, the columns extend in a direction perpendicular to the top surface, and the preferred growth direction is inclined upwards relative to the top surface.

3. A method according to claim 1 or claim 2 wherein the semiconductor material is a group III nitride material, and the preferential direction is the c direction.

4. A method according to any preceding claim wherein the top surface is in the (11-22) plane.

5. A method according to any preceding claim wherein the regular array is a rectangular, square, oblique, centred rectangular (rhombic) or hexagonal array.

6. A method according to any preceding claim wherein the semiconductor layer is supported on a substrate.

7. A method according to claim 6 wherein the substrate comprises at least one of sapphire, silicon and silicon carbide.

8. A method according to any preceding claim wherein each of the columns comprises a main part and a cap on the top of the main part during growth of the semiconductor material.

9. A method according to claim 8 wherein the cap is formed of at least one of silicon dioxide and silicon nitride.

10. A method according to claim 8 or claim 9 wherein the semiconductor material has a BSF propagation direction in which BSFs will propagate during growth of the material, and the height of the cap is at least high enough so that growth from the highest point on the side of the main part of one of the columns in the BSF propagation direction is blocked by the cap on another of the columns.

11. A method according to any one of claims 8 to 10 wherein the height of the cap high enough so that growth in the preferential growth direction from the highest point on the side of the main part of one of the columns is blocked by the cap on another of the columns.

12. A semiconductor template comprising an array of columns formed of semiconductor material, each including a cap formed of a mask material formed on its top, and a semiconductor material extending between the columns and over the top of the columns to form a continuous layer and having a preferential growth direction, wherein the columns are arranged in a regular array comprising a series of rows of columns, the rows being offset from each other in the direction perpendicular to the preferential growth direction, so that growth in the preferential growth direction from one of the columns in one of the rows extends between adjacent columns in the adjacent row.

13. A semiconductor template according to claim 12 wherein the regular array is a rectangular, square, oblique, centred rectangular, hexagonal, or rhombic array.

14. A semiconductor template according to claim 13 or claim 12 wherein each of the columns comprises a main part and a cap on the top of the main part.

15. A semiconductor template according to claim 14 wherein the height of the cap at least high enough so that growth from the highest point on the side of the main part of one of the columns, in the BSF propagation direction, is blocked by the cap on another of the columns.

16. A semiconductor template according to claim 14 or claim 15 wherein the height of the cap is such that growth in the preferential growth direction from the highest point on the side of the main part of one of the columns is blocked by the cap on another of the columns.

17. A semiconductor template according to any one of claims 12 to 16 wherein the semiconductor layer is supported on a substrate.

18. A semiconductor template according to claim 17 wherein the substrate comprises at least one of sapphire, silicon and silicon carbide.

19. A semiconductor template according to any of claims 12 to 18 wherein the cap is formed of at least one of silicon dioxide and silicon nitride.

20. A semi-polar semiconductor template comprising an array of columns formed of semiconductor material, each including a main part and a cap formed of a mask material formed on the top of the main part, and a semiconductor material extending between the columns and over the top of the columns to form a continuous layer with a top surface, wherein the semiconductor material has a preferential growth direction in which it tends to grow most rapidly, and the columns are arranged in a regular array comprising a series of rows of columns, the rows being offset from each other in a direction perpendicular to the preferential growth direction.

21. A method of making a semiconductor template comprising:
providing a semiconductor wafer;
etching the semiconductor wafer to form an array of columns each comprising a main part and a cap on its top; and
growing semiconductor material from the main parts of the columns over the columns; wherein
the material has a BSF propagation direction in which BSFs will propagate, and the height of the caps is such that growth from the top of the main part of each column, in the BSF propagation direction, will be blocked by the cap of another of the columns.

22. A method according to claim 21 wherein the semiconductor material has a preferential growth direction in which it grows most rapidly from the columns, and the height of the cap is high enough so that growth from the top of the main part of at least some of the columns in the preferential growth direction will be blocked by the cap of the nearest neighbour in the preferential growth direction.

23. A semiconductor template comprising: an array of columns of semiconductor material each comprising a main part with a cap on its top; and a semiconductor material grown between the columns and over the columns to form a continuous layer; wherein the material has a BSF propagation direction in which BSFs will propagate, and the height of the caps is such that growth from the top of the main part of each of the columns, in the BSF propagation direction, is blocked by the cap of another of the columns.

24. A method of making a semi-polar semiconductor template comprising:
providing a semi-polar semiconductor wafer;
etching the semiconductor wafer to form a regular semiconductor structure comprising a plurality of semiconductor regions with a plurality of gaps between the regions, each of the regions having a sidewall facing a respective one of the gaps, and
growing semiconductor material over the semiconductor structure; wherein
the semiconductor material has a preferential growth direction in which growth proceeds most rapidly from each of the sidewalls, and each of the sidewalls has at least a part which faces a vertical centre line of the respective one of the gaps so that growth in the preferential direction from said part extends towards said vertical centre line.

25. A semiconductor template comprising a regular semiconductor structure comprising a plurality of semiconductor regions with a plurality of gaps between the regions, each of the regions having a sidewall facing a respective one of the gaps, and a semiconductor material formed within the gaps and over the top of the columns to form a continuous layer and having a preferential growth direction, wherein each of the sidewalls has at least a part which faces a vertical centre line of the respective one of the gaps.

26. A method of making a semi-polar semiconductor template comprising:
providing a semi-polar semiconductor wafer;
etching the semiconductor wafer to form a regular semiconductor structure comprising a plurality of semiconductor regions with a plurality of gaps between the regions, each of the regions having a sidewall facing a respective one of the gaps, wherein the gaps are arranged in parallel rows,
growing semiconductor material over the semiconductor structure; wherein
the semiconductor material has a preferential growth direction in which growth proceeds most rapidly from each of the sidewalls, each of the rows extends in the direction perpendicular to the preferential growth direction, and the rows are offset from each other in the direction perpendicular to the preferential growth direction.

27. A method according to claim 26 wherein the rows are offset from each other in the direction perpendicular to the preferential growth direction by a distance equal to half of the period of the gaps.

28. A method according to any one of claim 24, 26 or 27 wherein the regions comprise columns.

29. A method according to any one of claim 24, 26 or 27 wherein the gaps comprise holes.

30. A method according to claim 29 wherein the sidewall of each of the holes is flat.

31. A method according to any one of claims 24 or 26 to 30 wherein at least a part of the sidewall of each of the holes faces in the direction of the horizontal component of the preferential growth direction.

32. A semiconductor template comprising a regular semiconductor structure comprising a plurality of semiconductor regions with a plurality of gaps between the regions, each of the regions having a sidewall facing a respective one of the gaps, and a semiconductor material formed within the gaps and over the top of the columns to form a continuous layer and having a preferential growth direction, wherein the semiconductor material has a preferential growth direction in which growth proceeds most rapidly from each of the sidewalls, the gaps are arranged in rows, each of the rows extends in the direction perpendicular to the preferential growth direction, and the rows are offset from each other in the direction perpendicular to the preferential growth direction.

33. A method of making a semiconductor template substantially as described herein with reference to any one or more of the accompanying drawings.

34. A semiconductor template substantially as described herein with reference to any one or more of the accompanying drawings.
